(19) United States
(12) Patent Application Publication
(10) Pub. No.: US 2004/0182156 A1
(43) Pub. Date: Sep. 23, 2004

(54) Capacitive-type semiconductor sensor having shared conductive pads for multiple sensor chips

(75) Inventor: Keisuke Goto, Obu-city (JP)

Correspondence Address: POSZ & BETHARDS, PLC, 11250 ROGER BACON DRIVE, SUITE 10, RESTON, VA, 20190, US

(73) Assignee: DENSO CORPORATION

(21) Appl. No.: 10/791,891

(22) Filed: Mar. 4, 2004

(30) Foreign Application Priority Data
Mar. 20, 2003 (JP) 200-78706

(51) Int. Cl. G01P 15/125; H01L 27/00

(52) U.S. Cl. 73/514.32; 257/414

(57) ABSTRACT

In a capacitive-type semiconductor sensor, a pad for fixed electrodes of a sensor chip operable in one direction is also used in common as a pad for the other fixed electrodes of the other sensor chip operable in another direction. Further, a wiring from the common pad for the one sensor chip and a wiring from the common pad for the other sensor chip are symmetrically formed. The sensor chips may be arranged to be operable in two perpendicularly crossing directions or in two reverse directions.

### CROSS REFERENCE TO RELATED APPLICATION

This application is based on and incorporates herein by reference Japanese Patent Application No. 2003-78706 filed on Mar. 20, 2003.

### FIELD OF THE INVENTION

The present invention relates to a capacitive-type semiconductor sensor having a plurality of single axis sensor chips which are formed on a single semiconductor substrate and detect dynamic or physical quantities, such as uniaxial acceleration, based on the capacitances between fixed electrodes and movable electrodes.

### BACKGROUND OF THE INVENTION

Various capacitive-type semiconductor sensors have been conventionally proposed. For example, JP-9-113534 discloses a sensor that detects acceleration in three axial directions, x, y and z directions, based on variation in capacitance between fixed electrodes and movable electrodes. For example, a capacitive-type semiconductor sensor for detecting acceleration in one axial direction (X direction) is constructed as illustrated in FIGS. 4A to 4C.

In FIGS. 4A to 4C, grooves 11 are formed in a semiconductor layer of Si or the like of a semiconductor substrate 10. Thus, a plurality of sets of fixed electrodes 1 and movable electrodes 2 are opposed to each other in the X direction to produce capacitance therebetween. A weight or trunk 3 is extended in the X direction, and the movable electrodes 2 are comprised of electrode arms 2a formed on the trunk 3 in the Y directions (positive and negative directions) like teeth of a comb. A beam 4 is formed at both axial ends of the trunk 3. The fixed electrodes 1 are comprised of electrode arms 1a and 1b arranged in the Y directions so that they are opposed to the movable electrodes 2 and respectively connected to electric conductive pads 5a and 5b formed of Al or the like. The movable electrodes 2 are connected to a pad 5c. The pads 5a, 5b, and 5c are connected to the outside through other pads on a mother board (not shown) or the like by wire bonding or the like.

The electrode arm 2a is placed between adjacent fixed electrode arms 1a and 1b. If acceleration is applied in the X direction, the beams 4 are displaced in the X direction together with the trunk 3 and the movable electrodes 2. Thereby, the distances between the fixed arms 1a and 1b and the movable arms 2a are varied. As a result, the capacitance CS1 between the fixed arm 1a and the movable arm 2a and the capacitance CS2 between the fixed arm 1b and the movable arm 2a are varied.

FIG. 5 illustrates an electric equivalent circuit of the capacitive-type sensor. In the figure, a pulse voltage Vcc is applied to the fixed arms 1a and 1b. Variation AC in the capacitances CS1 and CS2 (ΔC=CS1−CS2) is taken out of the movable electrode 2 (arm 2a). The voltage taken out is converted into a voltage expressed as (CS1−CS2)·Vcc/Cf through a switched capacitor circuit 5 so that the applied acceleration is detected as an output voltage (detection signal) of the switched capacitor circuit 5.

FIG. 6A illustrates a conventional two axis sensor wherein two single axis sensor chips 10X and 10Y are placed on a single or common semiconductor substrate 10 to be operable in response to accelerations in the X direction and Y direction, respectively. Use of such a two axis sensor in an air bag for vehiclemakes it possible to detect front collision (for example, in the X direction) and side collision (for example, in the Y direction) to actuate an air bag.

However, in the conventional two axis sensors wherein two single axis sensor chips 10X and 10Y are disposed in the X direction and in the Y direction independently of each other as illustrated in FIG. 6, the pads 5a, 5b and 5c for the single axis sensor chip 10X and pads 15a, 15b and 15c for the single axis sensor chip 10Y. Thus, the number of pads is doubled and this leads to an increased mounting area and an increased number of times of wire bonding. Further, the same voltage Vcc is applied to both sets of the pads (pads 5a and 5b, and pads 15a and 15b). Therefore, a parasitic capacitance difference is produced, and this causes phase shift between the detection signals in the respective directions.

### SUMMARY OF THE INVENTION

It is an object of the present invention to provide a capacitive-type semiconductor sensor with a plurality of single axis sensors formed on a single semiconductor substrate, wherein the numbers of pads for the sensors can be reduced and the parasitic capacitances of the sensors can be equalized to prevent phase shift between detection signals.

To attain the above object, the capacitive-type semiconductor sensor according to the present invention is constructed with pads, which are connected to fixed electrodes of a plurality of single axis sensors, are shared. Therefore, the numbers of pads for the sensors can be reduced. Further, wirings for the fixed electrodes of a plurality of the single axis sensors and the single pads are symmetrically formed. Therefore, the parasitic capacitances of the sensors can be equalized to prevent phase shift between detection signals.

### BRIEF DESCRIPTION OF THE DRAWINGS

The above and other objects, features and advantages of the present invention will become more apparent from the following detailed description made with reference to the accompanying drawings. In the drawings:

FIG. 1 is a schematic plan view illustrating a first embodiment of a capacitive-type semiconductor sensor according to the present invention;

FIG. 2 is a schematic plan view illustrating a second embodiment of a capacitive-type semiconductor sensor of the present invention;

FIG. 3 is a schematic plan view illustrating a third embodiment of a capacitive-type semiconductor sensor of the present invention;

FIG. 4A is a schematic plan view illustrating a conventional single-axis capacitive-type semiconductor sensor, and FIGS. 4B and 4C are schematic cross-sectional views illustrating the conventional sensor shown in FIG. 4A;

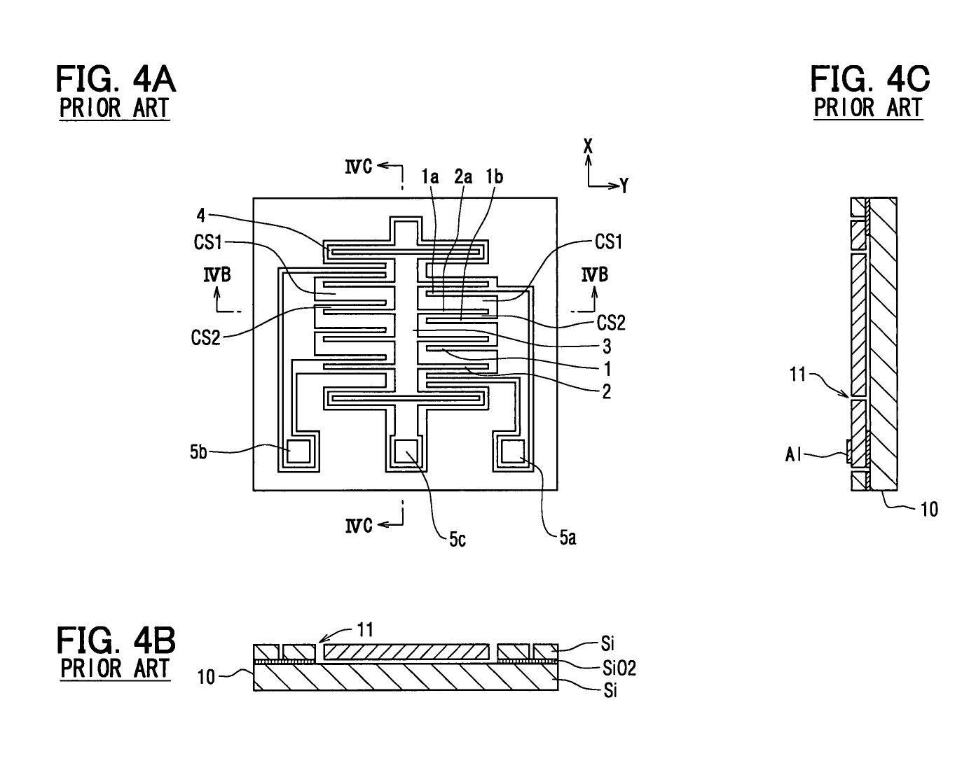

FIG. 5 is an electric circuit diagram illustrating an equivalent circuit of the conventional sensor shown in FIG. 4A and a switched capacitor circuit; and

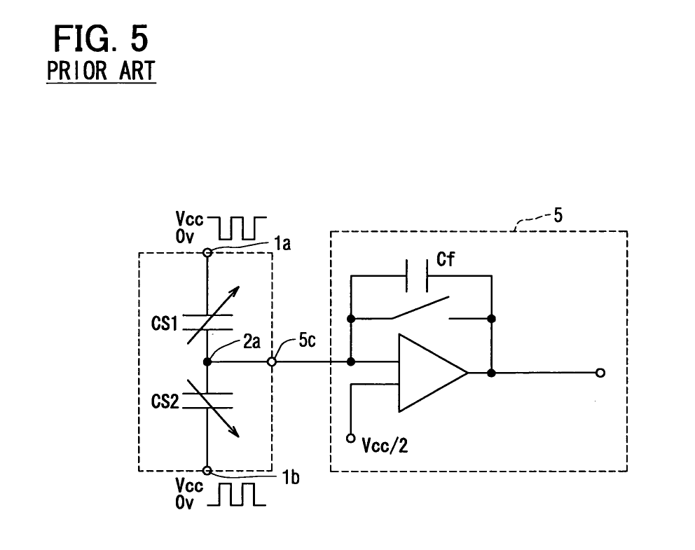

FIG. 6 is a schematic plan view illustrating a conventional two-axis capacitive-type semiconductor sensor.

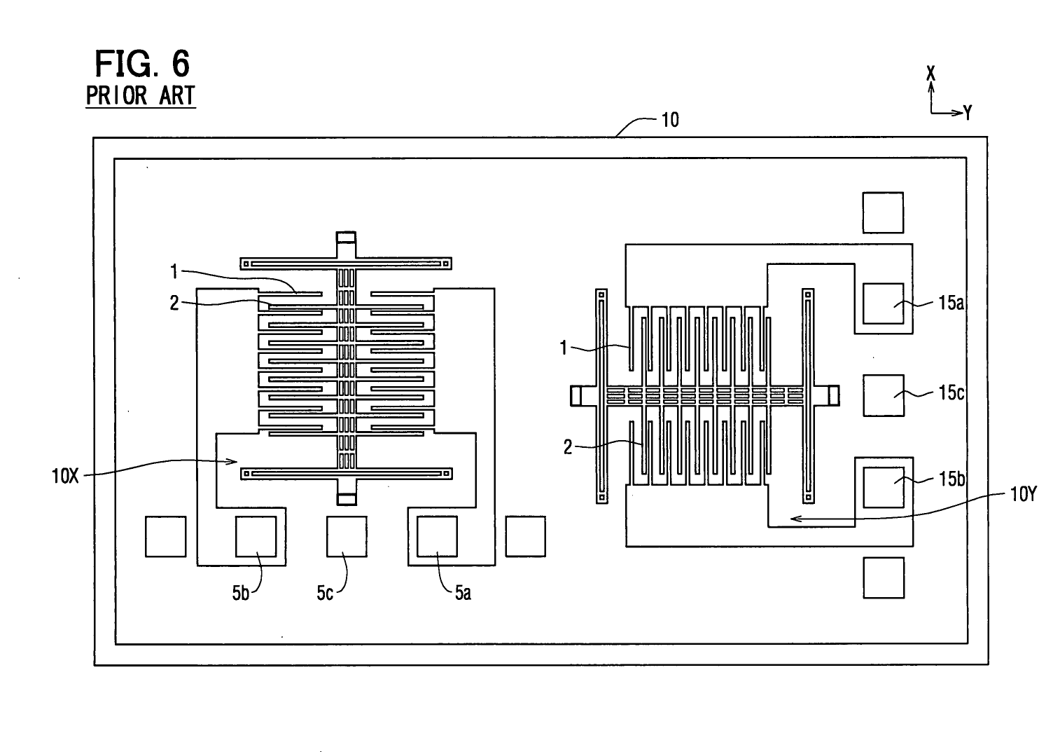

### DETAILED DESCRIPTION OF THE PREFERRED EMBODIMENTS

(First Embodiment)

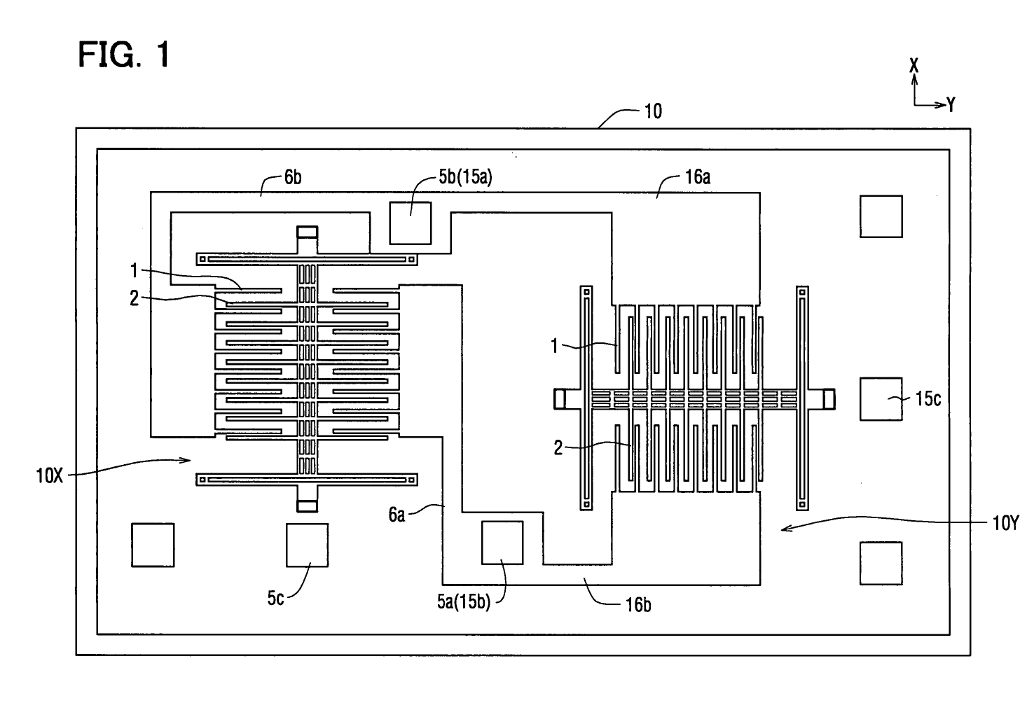

Referring to FIG. 1, a capacitive-type semiconductor sensor chip 10X operable in response to the X direction acceleration and a capacitive-type semiconductor sensor chip 10Y operable in response to the Y direction are formed on the same semiconductor substrate 10. A pad 5b for fixed electrodes 1 of the sensor chip 10X is also used in common as a pad 15afor the fixed electrodes 1 of the sensor chip 10Y. Further, a pad 5a for fixed electrodes 1 of the sensor chip 10X is also used in common as a pad 15b for fixed electrodes 1 of the sensor chip 10Y. Pad 5c and 15c for movable electrodes 2 of the sensor chip 10X and 10Y are used to take out the respective detection signals. Therefore, the pads 5c and 15c are separated from each other.

Further, a wiring 6a from the pad 5a (pad 15b) to the fixed electrodes 1 for the sensor chip 10X and a wiring 16b from the pad 5a (pad 15b) to the fixed electrodes 1 for the sensor chip 10Y are formed similar to each other. Also, a wiring 6b from the pad 5b (pad 15a) to the fixed electrodes 1 for the sensor chip 10X and a wiring 16a from the pad 5b (pad 15a) to the fixed electrodes 1 for the sensor chip 10Y are formed similar or symmetrical to each other.

Owing to sharing of pads 5a (15b) and 5b (15a) for the fixed electrodes 1 of the sensors chips 10X and 10Y, phase differences in pulse voltage vcc applied to the fixed electrodes 1 of the sensor chips 10X and 10Y can be reduced. Further, the mounting area and the number of times of wire bonding can be reduced. In addition, owing to similarly or symmetrically forming the wirings from the pads 5b and 5a (pads 15a and 15b) for the sensor chips 10A and 10Y, the wiring resistance in each direction and the parasitic capacitance between each sensor chip and the semiconductor substrate 10 can be equalized. Therefore, phase differences in pulse voltage Vcc can be reduced.

(Second Embodiment)

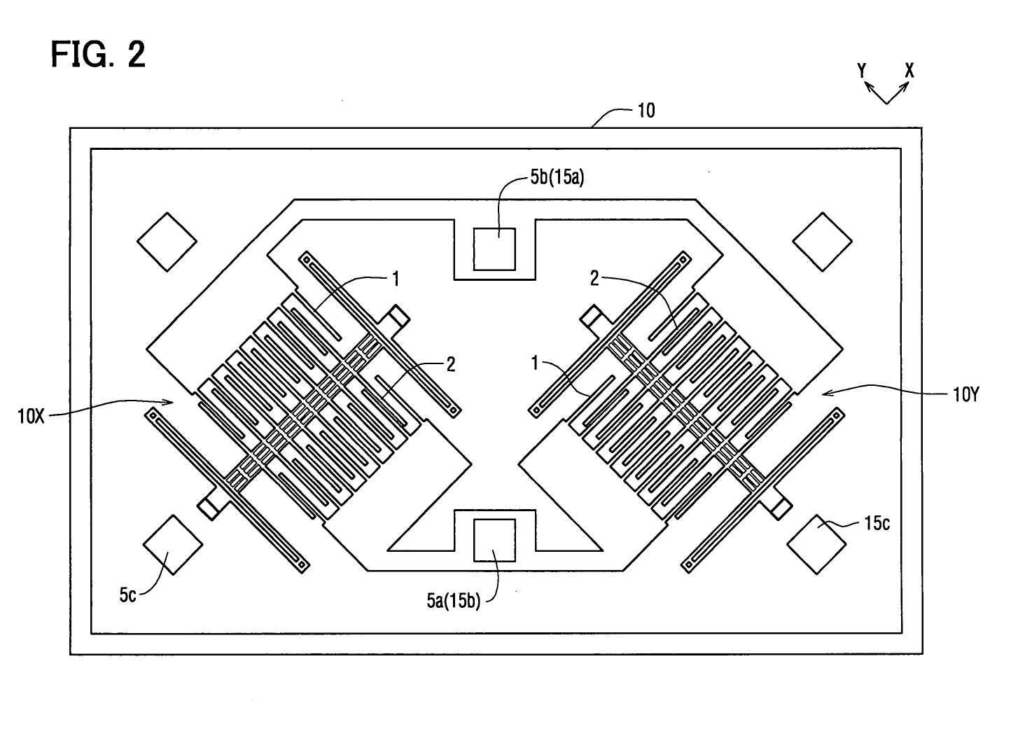

In the first embodiment, the sensor chips 10X and 10Y are disposed on the semiconductor substrate 10 perpendicularly to each other, that is, in the vertical and horizontal directions in FIG. 1. However, the sensor chips 10X and 10Y may be disposed in other manners. As illustrated in FIG. 2, for example, the sensor chips 10X and 10Y may be slantingly disposed on the rectangular semiconductor substrate 10 in the directions of +45 degrees and −45 degrees. The second embodiment is suitable for cases where there are limitations on the orientation of places of installation in a vehicle or the like.

(Third embodiment)

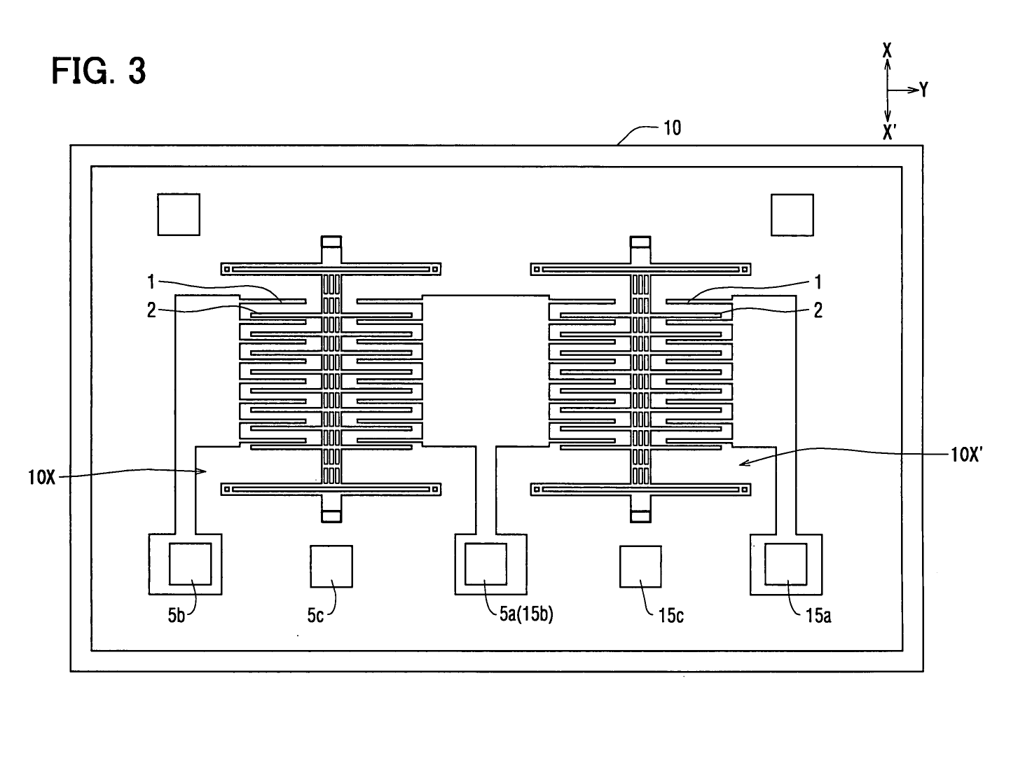

As illustrated in FIG. 3, for example, the two single axis sensor chips 10X and 10X′ may be disposed in parallel with each other. With the third embodiment, if a vehicle is given an impact from front and then bumped from behind, as in a pileup, the accelerations in both directions X and X′ reverse to each other can be detected.

The present invention should not be limited to the disclosed embodiment, but may be modified in various ways.

What is claimed is:

1. A capacitive-type semiconductor sensor comprising:
a single semiconductor substrate;
a plurality of sensor chips formed on the single substrate and operable in respective single axes, each of the sensor chips having fixed electrodes and movable electrodes for producing a detection signal corresponding to capacitances between the fixed electrodes and the movable electrodes;
shared pads connected to the fixed electrodes of the plurality of the sensor chips and shared thereby; and
wirings connecting the fixed electrodes and the shared pads of the plurality of sensor chips are symmetrically formed.

2. The capacitive-type semiconductor sensor according to claim 1, wherein two of the sensor chips are formed on the single substrate at an angle of 90 degrees to be operable in perpendicularly crossing directions.

3. The capacitive-type semiconductor sensor according to claim 1, wherein two of the sensor chips are formed on the single substrate in parallel with each other to be operable in reverse directions.
